(19) United States
(12) Patent Application Publication
(10) Pub. No.: US 2016/0336183 A1
(43) Pub. Date: Nov. 17, 2016

(54) METHODS, APPARATUS AND SYSTEM FOR FABRICATING FINFET DEVICES USING CONTINUOUS ACTIVE AREA DESIGN

(71) Applicant: GLOBALFOUNDRIES INC., Grand Cayman (KY)

(72) Inventors: Lei Yuan, Sunnyvale, CA (US); Jongwook Kye, Pleasonton, CA (US); Mahbub Rashed, Santa Clara, CA (US)

(73) Assignee: GLOBALFOUNDRIES INC., Grand Cayman (KY)

(21) Appl. No.: 14/712,767

(22) Filed: May 14, 2015

(51) Int. Cl. H01L 21/285; H01L 29/78; H01L 21/67; H01L 29/40; H01L 29/417; H01L 29/66; H01L 29/45

(52) U.S. Cl. CPC H01L 21/28518; H01L 29/66795; H01L 29/785; H01L 29/458; H01L 29/401; H01L 29/41791; H01L 21/67063; H01L 21/6715

(57) ABSTRACT

At least one method, apparatus and system disclosed herein for processing a semiconductor wafer using a continuous active area design for manufacturing a finFET device. A first gate structure of a continuous active area design is formed in a first layer of the wafer. A first hard mask layer is deposited. A portion of the first hard mask layer is removed based upon a first trench silicide (TS) pattern and a second TS pattern. A full stripe first trench silicide (TS) structure and a second TS structure are formed. A first TS capping layer is deposited above the first TS structure and a second TS capping. The first TS capping layer is removed and a source/drain contact structure (CA) is formed above the first TS structure in a second layer of the semiconductor wafer. A gate contact structure (CB) is formed above the gate structure in the second layer.

### BACKGROUND OF THE INVENTION

1. Field of the Invention

Generally, the present disclosure relates to the manufacture of sophisticated semiconductor devices, and more specifically, to various methods for fabricating finFET devices using continuous active area layouts.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A FET is a device that typically includes a source region, a drain region, a channel region that is positioned between the source region and the drain region, and a gate electrode positioned above the channel region. Current flow through the FET is controlled by controlling the voltage applied to the gate electrode. If a voltage that is less than the threshold voltage of the device is applied to the gate electrode, then there is no current flow through the device (ignoring undesirable leakage currents, which are relatively small). However, when a voltage that is equal to or greater than the threshold voltage of the device is applied to the gate electrode, the channel region becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the channel from being adversely affected by the electrical potential of the drain. This is sometimes referred to as a so-called short channel effect, wherein the characteristic of the FET as an active switch is degraded.

In contrast to a planar FET, which has a planar structure, there are so-called 3D devices, such as an illustrative finFET device, which is a 3-dimensional structure. More specifically, in a finFET, a generally vertically positioned, fin-shaped active area is formed and a gate electrode encloses both of the sides and the upper surface of the fin-shaped active area to form a trigate structure so as to use a channel having a 3-dimensional structure instead of a planar structure. In some cases, an insulating cap layer, e.g., silicon nitride, is positioned at the top of the fin and the finFET device only has a dual-gate structure.

FinFET designs use “fins” that may be formed on the surface of a semiconductor wafer using selective-etching processes. The fins may be used to form a raised channel between the gate and the source and drain of a transistor. The gate is then deposited such that it wraps around the fin to form a frigate structure. Since the channel is extremely thin, the gate would generally have a greater control over the carriers within. However, when the transistor is switched on, the shape of the channel may limit the current flow. Therefore, multiple fins may be used in parallel to provide greater current flow for increased drive strength.

FIG. 1 illustrates a stylized cross-sectional depiction of a state-of-the-art finFET device. A finFET device 100 illustrated in FIG. 1 comprises a plurality of “fins” 110. The semiconductor device may be position to a vertical orientation, creating one or more fins 110. The source and drain of the finFET are placed horizontally along the fin. A high-k metal gate 120 wraps over the fin, covering it on three sides. The gate 120 defines the length of the finFET device. The current flow occurs along an orthogonal crystal plane in a direction parallel to the plane of the semiconductor wafer. The electrically significant height of the fin (labeled H) is typically determined by the amount of oxide recess in the fin reveal step and hence is constant for all fins 110.

The thickness of the fin (labeled T_{fi}) determines the short channel behavior of the transistor device and is usually small in comparison with the height H of the fin 110. The pitch (labeled P) of the fins is determined by lithographic constraints and dictates the wafer area to implement the desired device width. A small value of the pitch P and a large value of the height H enable a better packing of the devices per square area resulting in a denser design, or more efficient use of silicon wafer area.

The scaling down of integrated circuits coupled with higher performance requirements for these circuits have prompted an increased interest in finFETs. FinFETs generally have the increased channel widths, which includes channel portions formed on the sidewalls and top portions of the fins. Since drive currents of the finFETs are proportional to the channel widths, finFETs generally display increase drive current capabilities.

Designers often use pre-designed basic cells to form layouts of more complex cells comprising finFET devices. In a CMOS integrated circuit, PMOS and NMOS transistor pairing are often used to form circuit cells. For example, FIG. 2 illustrates a stylized cross-sectional depiction of a state-of-the-art single diffusion-break cell design. FIG. 2 depicts a two abutted CMOS single diffusion-break finFET cells 201, 202, each of which comprises a PMOS portion 210 and a complimentary NMOS portion 220. A plurality of cells, such as the exemplary cells 201, 202, may be placed and routed to form more complex circuitry.

The cells 201, 202 each comprises a single diffusion break, i.e., a single dummy gate 240 that separates active areas. The cells 201, 202 each also comprises a plurality of active gate formations 230, 232 that are part of the transistors of the cells 201, 202. The active gates can be categorized into outer active gates 230 and inner active gates 232. The outer active gates 230 are used to form outer transistors, while the inner active gates 232 are used to form inner transistors. One disadvantage associated with the single diffusion break cell 200 includes a problem with inconsistency of source drain formation between the outer transistors and the inner transistors. The cells 201, 202 each also comprises a plurality of source/drain fins 270. During processing of wafer based on the cells 201, 202, the transistors relating to the outer gate formations 230 may be processed slightly differently from the transistors relating to the inner gate formations 232 as a result of process variations. For example, as a result of process variations, the source/drain process on the cell boundary area (205) and the inter-cell area (206) will be different, resulting in device variations between the inner transistors and the outer transistors. In addition, the source/drain contact resistance in the cell boundary area (205) would be often higher than inter-cell area (206) due to partial active area, which may degrade transistor performance. This may result in performance differences between transistors having inner gate formations 232, and the transistors having outer gate formations 230. This may be problematic in an integrated circuit device formed from the cells 200.

In order to address the problems of the single diffusion-break configuration cells, designers have proposed the use of double diffusion-break configuration cells. For example, FIG. 3 illustrates a stylized depiction of a top view of a prior art double diffusion break cell. FIG. 3 illustrates a set of CMOS double diffusion-break finFET cell 300, which comprises two diffusion-break finFET cells abutted to form the set of cells 300. Each of the cell of the set of CMOS double diffusion-break finFET cell 300 comprises a PMOS portion 310 and a complimentary NMOS portion 320. In double diffusion designs, two abutted cells are separated by two dummy gates and the active area on the cell edges are always tucked under dummy gates in order to minimize the source/drain process variation on cell edges. A plurality of cells 300 may be placed and routed to form more complex circuitry.

The set of cells 300 comprises a double diffusion-break, i.e., two dummy gates 342 that encompass each active area, such that each active area is isolated from the other. The set of cell 300 comprises a plurality of active gate formations 330 that are part of the transistors of the set of cell 300. Unlike the inner and outer active gate configurations of the single diffusion-break cell 200, the double diffusion-break configuration calls for having only inner active gate formations. The set of cell 300 also comprises a plurality of source/drain fins 370. The dummy gate formations 342 are placed on the edge of each of the active regions in the set of cell 300. As such, the active gate formations 330 are all inner gates, and thus, unlike the single diffusion-break cell 200, the active gate formations 330 have consistent features. However, one disadvantage of the double diffusion-break configuration is the increased use of space to house the multiple edge dummy gates 340. Further, this increased usage of space does not offer any additional functionality over single diffusion-break configurations.

In order to address the problems associated with double diffusion-break configuration cells, designers have proposed the use of continuous active area configuration cells. For example, FIG. 4 illustrates a stylized depiction of a top view of a prior art continuous active area (“RX”) cell. The continuous RX cell is designed to provide the lower area advantage of the single-diffusion cells, while providing the advantage of the greater consistency of the gate performance of the double-diffusion cells.

FIG. 4 shows a continuous PMOS region 410 and a complementary, continuous NMOS region 420. As shown in FIG. 4, a set of two abutted cells 400 contains continuous active areas that are isolated from each other by PMOS isolation gates 440 and NMOS isolation gates 442.

Unlike the single and double diffusion-break cells, the active areas of the continuous RX cells 400 are merged together. However, since the active areas are merged together, one active area must be electrically isolated from the other. The active areas of the continuous RX cells 400 are isolated by individual gates 440, 442 that are separate, i.e., one gate 440 for the PMOS region 410 for providing an isolation PMOS, and another gate 442 for the NMOS region 420 for providing an isolation NMOS. The gates 440, 442 are the result of a single gate that was cut in order to provide isolation. The electrical isolation is achieved by the two isolation transistors 440, 442 that are maintained at “off” operation. The gate 440 of the isolation PMOS is operatively coupled to power supply VDD 450, and the gate 442 of the isolation NMOS is operatively coupled to power supply VSS such that both isolation transistors 440, 442 are always turned off and thus, the two cell portions of the abutted cells 400 are electrically isolated from each other.

The two abutted cells 400 also comprises a plurality of source/drain fins 470. Moreover, each of the dummy gates 440, 442 are tied to respective power supplies for providing isolation. The PMOS dummy gate 440 is tied to a V_{DD} power supply 450, and the NMOS dummy gate 442 is tied to a V_{SS} power supply 460. In this manner, isolation between the active areas of the cell 400 is achieved while providing a continuous configuration of active areas.

finFET devices generally require “full stripe” source/drain contact regions to connect all active fins. For example, FIG. 5 illustrates a more detailed stylized depiction of the top view of a prior art continuous (RX) cell 500 that depicts full stripe source/drain regions. FIG. 5 illustrates full stripe source/drain contacts to the continuous RX cell of FIG. 4. The PMOS region 410 comprises a plurality of PMOS full stripe source/drain (S/D) contacts 510. The NMOS region 420 comprises a plurality of NMOS full stripe S/D contacts 512. The cell 500 comprises PMOS dummy gates 440 and NMOS dummy gates 442. The dummy gates 440, 442 generally form working transistors that can be turned off. However, the dummy gates 440, 442 do not contribute to circuit operations other than isolating two function cells. Further, the cell 500 comprises active gates 530.

As described above in the context of FIG. 4, in order to provide isolation between active areas, the isolation PMOS gates 540 are tied to V_{DD}, and the isolation NMOS gates 542 are tied to V_{SS}. Continuing referring to FIG. 5, in order to tie the gates 540, 542 to power signals (V_{DD} and V_{SS}), power rails are formed. The PMOS gate 540 is connected to V_{DD} power rail through CA/CB gate tie-up structure 561. The NMOS gate 542 is connected to V_{SS} power rail through CA/CB gate tie-up structure 551. Generally, the source or the drain contacts are also connected to power signals using the power rails.

In the example of FIG. 5, a PMOS source contact 532 is connected to V_{DD} power rail through a via layer and the dummy gate 540 is tied to VDD power rail through a CA and CB connection. In this case, the other side of the PMOS gate 540, the adjacent full stripe S/D contact is a PMOS drain contact (520). Due to the usage of CA/CB gate tie-up, which is used to connect the PMOS dummy gate 540 and the PMOS source contact 532 to V_{DD}, the close proximity of the PMOS drain contact 520 presents a significant risk of shorting to the power rail 560. This is particularly a problem with 10 nm or less finFET devices.

Similarly, an NMOS source contact 552 is connected to V_{SS} using the power rail 565 power rail through a via layer and the dummy gate 542 is tied to VSS power through a CA and CB connection. In this case, the other side of the NMOS dummy gate 542, the adjacent full stripe S/D contact is an NMOS drain contact (554). Due to the usage of the CA/CB gate tie-up, which is used to connect the NMOS dummy gate 542 and the NMOS source contact 552 to V_{SS}, the close proximity of the NMOS drain contact 554 also presents a significant risk of shorting with the power rail 565, particularly for finFET devices with dimensions of 10 nm or less. Similarly, the close proximity of the PMOS drain contact 520 also presents a significant risk of shorting with the power rail 560. These shorting problems can cause various process problems and device operation errors.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus and system for processing a semiconductor wafer using a continuous active area design for manufacturing a finFET device. A first gate structure of a continuous active area design is formed in a first layer of a semiconductor wafer. A first hard mask deposition process is performed for depositing a first hard mask layer upon the first layer. A portion of the first hard mask layer is removed based upon a first trench silicide (TS) pattern and a second TS pattern. A first trench silicide (TS) structure and a second TS structure of the continuous active area design are formed in the first layer based upon removing the portion of the hard mask layer. The first and second TS structures are full stripe structures. A first TS capping layer is deposited above the first TS structure and a second TS capping layer above the second TS structure. The first TS capping layer is removed and a source/drain contact structure (CA) is formed above the first TS structure in a second layer of the semiconductor wafer. A gate contact structure (CB) is formed above the gate structure in the second layer.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized cross-sectional depiction of a state-of-the-art finFET device;

FIG. 2 illustrates a stylized depiction of a top view of a prior art single diffusion break cell;

FIG. 3 illustrates a stylized depiction of a top view of a prior art double diffusion break cell;

FIG. 4 illustrates a stylized depiction of a top view of a prior art continuous active area cell;

FIG. 5 illustrates a more detailed stylized depiction of a top view of a prior art continuous active area cell;

FIG. 6 illustrates a flowchart depiction of a method for providing a continuous active area architecture, in accordance with embodiments herein;

FIG. 7 illustrates a stylized, top view depiction of a continuous active area layout of a finFET device, in accordance with embodiments herein;

FIG. 8 illustrates a stylized, cross-sectional depiction of the continuous active area layout of the finFET device of FIG. 8, in accordance with embodiments herein;

FIGS. 9-23 illustrate various stylized depiction of the steps for forming finFET device having a continuous active area, in accordance with some embodiments herein; and

FIG. 24 illustrates a stylized depiction of a system for fabricating semiconductor devices comprising finFET devices having a continuous active area, in accordance with embodiments herein.

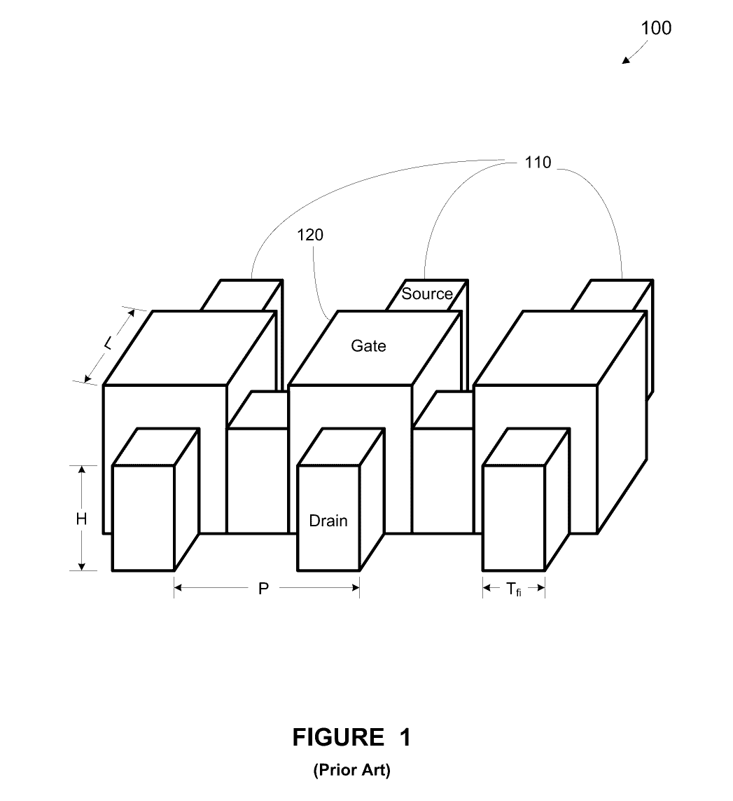

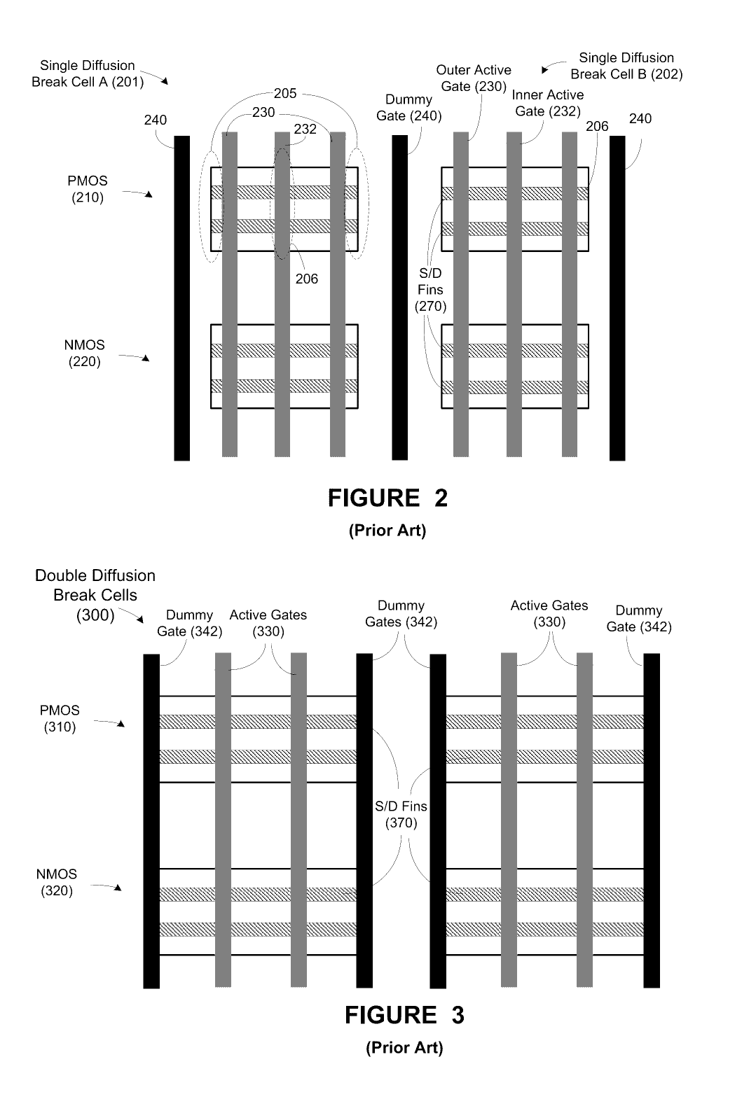

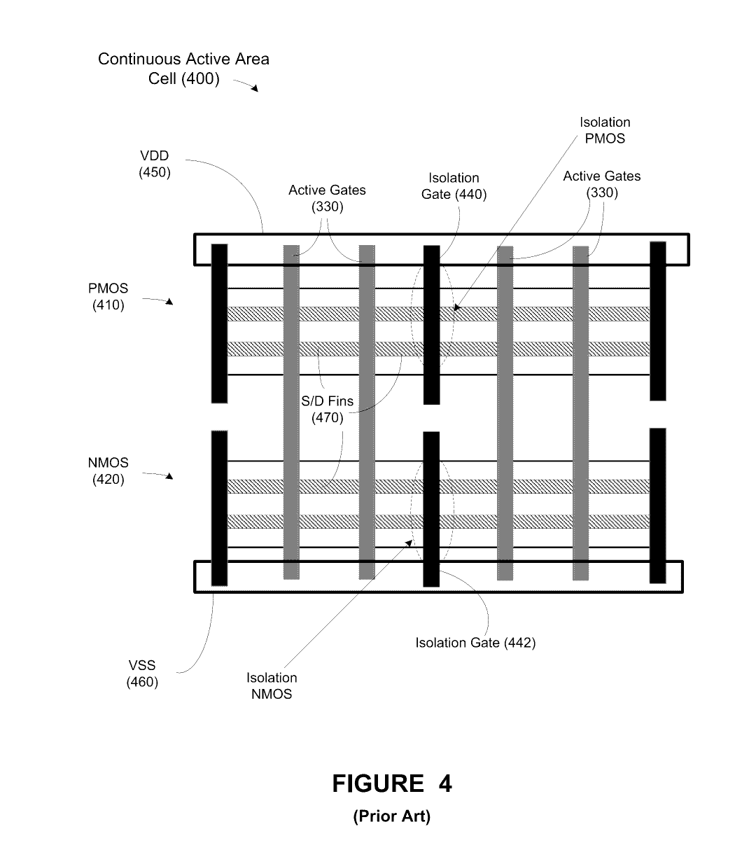

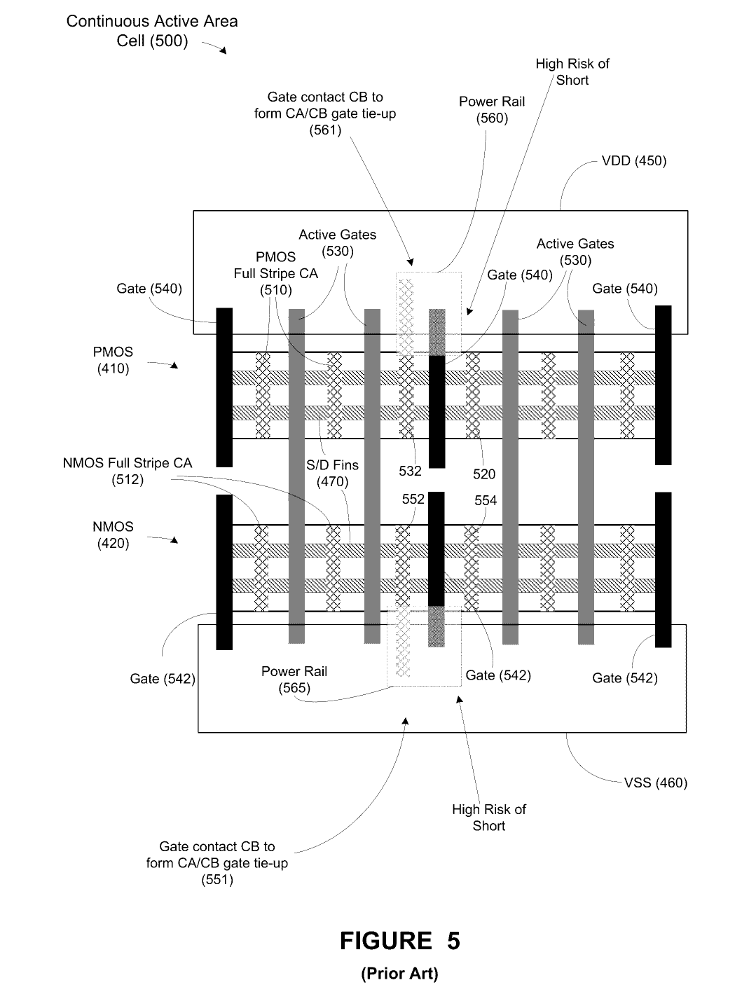

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached Figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for a continuous active area design that may be implemented in high density circuits, such as 10 nm and/or smaller designs. Embodiments herein provide for a middle of line (MOL) architecture that comprises a full stripe trench silicide (TS) feature, CA contacts and CB contacts. Embodiments herein also provide for a cap layer being formed atop the TS feature.

Embodiments herein provide for an integrated circuit comprising finFET devices, wherein the finFET devices comprise two-layer source/drain contact features. The two-layer source/drain contact feature of embodiments herein may comprise a first layer having a full stripe TS feature, and a second layer comprising a contact feature for providing a connection to a metal feature.

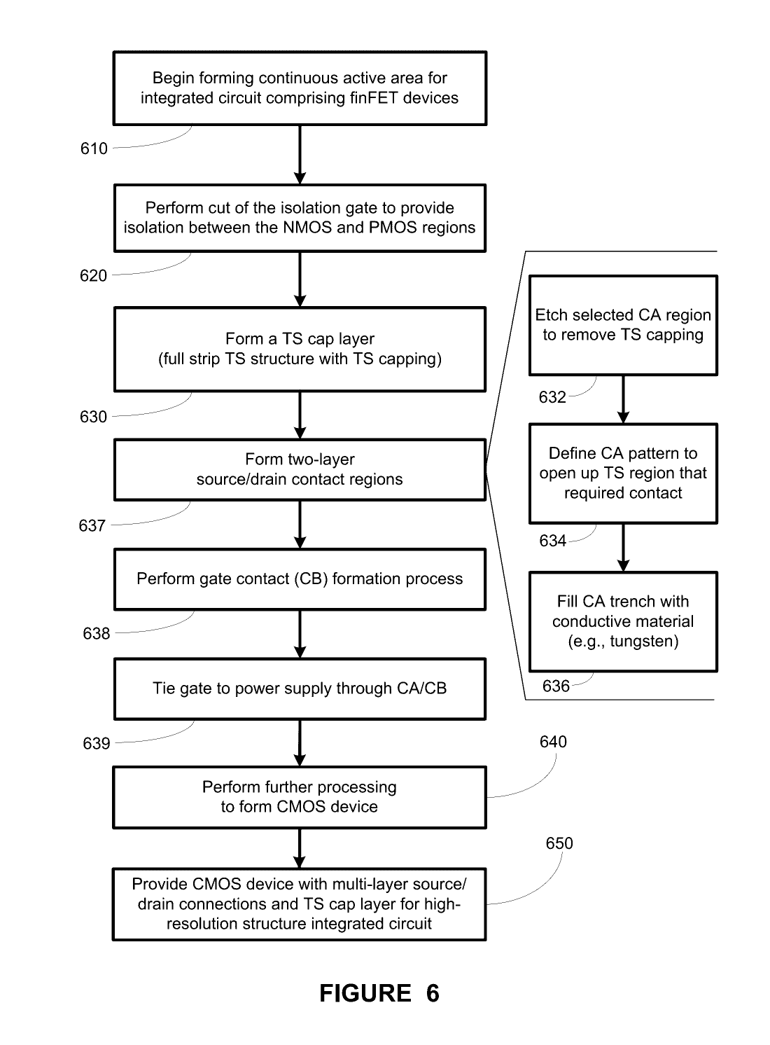

Turning now to FIG. 6, a flowchart depiction of a method for providing a continuous active area architecture comprising a two-layer source/drain contact feature, in accordance with embodiments herein, is illustrated. The continuous active area formation provided herein may be formed in 10 nm or smaller node/class semiconductor devices. The forming of one or more continuous active areas on a semiconductor wafer for manufacturing finFET devices, may be performed (block 610). The continuous active area formations may comprise advantages of double-diffusion dummy gates that have dummy gates on the outer edges of cells, while active gates are formed within the inner portions of the cells, resulting in more consistent characteristic of the active gates. Further, the continuous active area formations also comprise advantages of a single-diffusion cell with regard to usage of lower amounts of space for forming cells. Further, the gate that is formed between the cells used to form the continuous active area is cut to provide isolation (block 620).

A trench silicide (TS) cap layer is formed (block 630). Forming the TS cap layer comprises forming a full strip TS formation that connects to a via contact. In one embodiment, substantially the entire top portion of the TS formation is capped except for one or more portions where contact(s) to source or drain regions are desired.

Upon forming the TS cap layer, a multi-layer source/drain (S/D) contact region is formed (block 637). The source/drain contact region is formed above the TS cap layer provide connection of the source/drain regions to metal layers, e.g., for power or ground connections. The TS cap layer can be selectively etched away for isolating certain gates and for connecting other gates. That is, the TS cap layer has etch-selectivity to gate capping layers.

In order to form the multi-layer source/drain region, a source/drain contact (CA) pattern is defined, wherein the CA pattern is to be formed above a selected portion of the TS cap layer (block 632). The cap portion of the TS cap layer above the selected portion of the TS cap layer is etched (block 634). This etching opens up cap portion above the TS formation intended for the source/drain connection and provides a trench for forming the CA formation. The CA pattern is then formed above the etched portion above the TS cap layer by filling in the trench with conductive material (e.g., tungsten) (block 636). This provides a connection from the TS formation to other layers in the semiconductor wafer, through the CA formation.

A CB gate contact is subsequently formed (block 638). The cut gate portions are operatively coupled to power supply via the CA/CB structures (block 639). One portion of the cut gate is coupled to VDD, forming a PMOS isolation gate, while the other portion of the gate is coupled to VSS, forming an NMOS isolation gate.

Subsequent to forming the CA/CB formations and providing the isolation gates, further processing is performed on the semiconductor wafer for forming a CMOS device (block 640). Further details regarding the subsequent processing are provided below. As described below, this provides a CMOS device with multi-layer source/drain connections and TS cap layer for high-resolution (e.g., 10 nm or less node widths) integrated circuits (block 650).

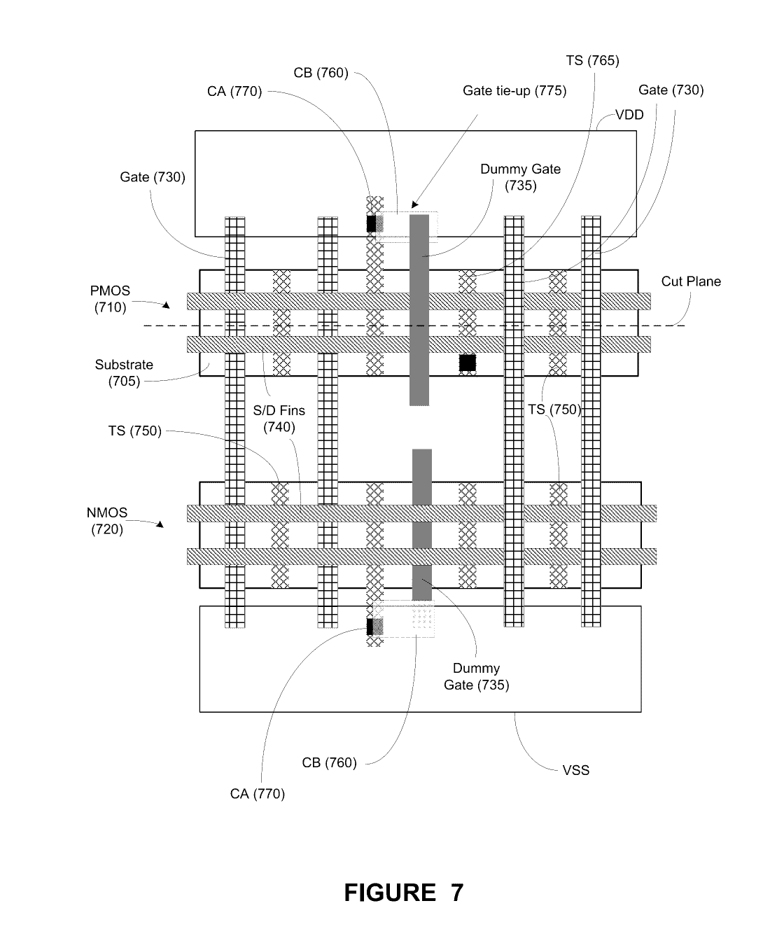

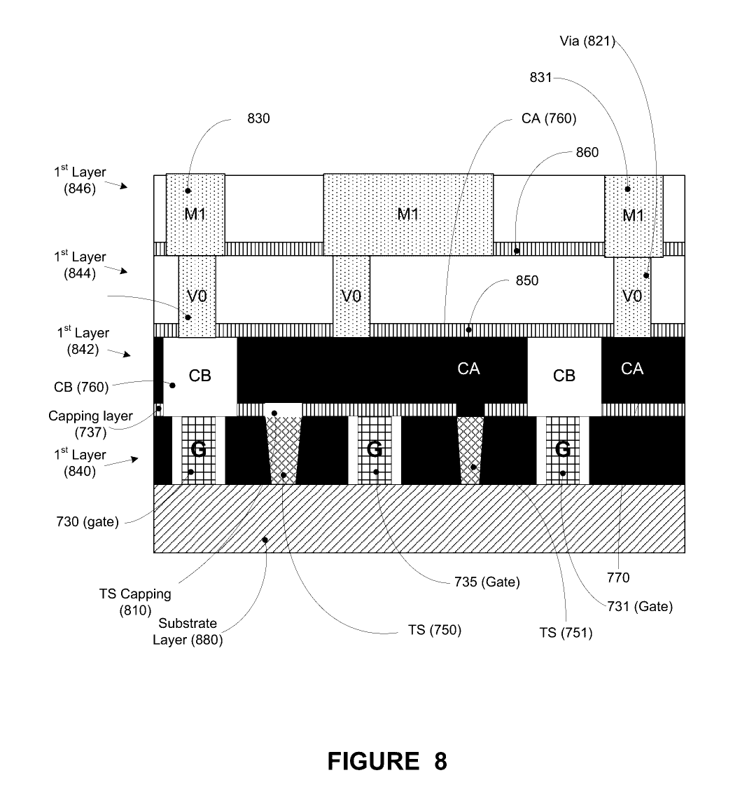

Turning now to FIG. 7 a stylized, top view depiction of a continuous active area layout of a finFET device, in accordance with embodiments herein, is illustrated. FIG. 7 illustrates a two-level source/drain contract region applied to a continuous cell architecture. The finFET device of FIG. 7 comprises a PMOS region 710 and a complimentary NMOS region 720. A CA feature 770 and a TS feature 765 connect a plurality of source/drain regions (fins) 740 to one or more metal layers (described below in FIG. 8).

The TS formations 750 are full strip trench silicide layers. The TS layer 750 may be formed such that it connects to the CA 770. The CA 770, in one embodiment, may be a “via-type” contact. In one embodiment, the CA layer 770 is electrically coupled to a metal-1 layer of a finFET device.

The finFET device of FIG. 7 also comprises a plurality of gates 730 and one or more dummy gates 735. One or more CB formations 760 are connected to the gate regions 730. In one embodiment, the CB formation 760 may be connected to the CA 770, wherein the connection also functions as a gate tie-up 775 to VDD. A cap layer may be formed on some TS formations 750 to prevent inadvertent connections (as shown in further details in FIG. 8). The cap layer over the TS formation 750 may be removed to provide a connection to a CA formation 770. The cap layer reduces the possibility of shorting between the CB formation 760 and the TS formation 765.

FIG. 8 illustrates a stylized, cross-sectional depiction of the continuous active area layout of the finFET device of FIG. 7, in accordance with embodiments herein. The cross-sectional view provided by FIG. 8 may refer to one or more cut planes (e.g., the cut plane line shown in FIG. 7) with reference to FIG. 7. FIG. 8 illustrates stylized depictions of four layers (1^{st} layer 840, 2^{nd} layer 842, 3^{rd} layer 844, and 4^{th} layer 846) that may be formed on a substrate layer 880.

A plurality of gate formations 730 may be formed on the first layer 840. Further, one or more dummy gates 731 may also be formed on the first layer 840. Atop the first layer 840, a gate capping layer 737 is formed for preventing electrical connections to the gates 735. The gate capping layer 737 may be formed stop the active gates so long as there is no CB connection to the gate. On other gates 730, the gate cap layer 737 is removed to allow for subsequent coupling with CB formations 760 that are formed on the 2^{nd} layer 842.

Moreover, a plurality of TS formations 780 are also formed in the 1^{st} layer 840. The TS formations are full stripe trench silicide layers. Atop the TS formation 750, a TS capping formation 810 is formed. Generally, the TS cappings 810 prevent connections to the TS formation 750. On a select TS formation 751, TS capping layer is removed to allow for subsequent coupling with CA formation 760.

Referring back to FIG. 7, the TS capping layer 810 is formed along the full run of the TS layer 780, except at the portion where the CA formation 770 is formed in order to connect to the TS layer 780. Continuing referring to FIG. 8, the TS capping layer 810 is removed atop the TS layer 751 so that it can be connected to a CA formation 760 that is formed (on the 2^{nd} layer 842) above the TS layer 751.

As shown in FIG. 8, on the 2^{nd} layer 842, a CA formation is formed over the TS formation 781, wherein the TS formation 780 is capped by the TS capping 810. Further a CB formation 760 is formed over the gate 730. On another gate (gate 731), a CB formation 760 is formed. Further, a CA formation 770 is formed such that it connects to the CB formation 760. This corresponds to the gate tie-up over continuous RX 775 of FIG. 7.

Above the 2^{nd} layer 842, a dielectric capping layer 850 is formed. Portions of the dielectric capping layer 850 are removed to allow for connections on portions of the 2^{nd} layer 842, such as the CB formation 760 and the CA formation 731. The 3^{rd} layer 844 is formed above the dielectric capping layer 850.

A plurality of vias may be formed on the 3^{rd} layer 844. For example, a via V₀ 820 is formed above the CB formation 760, connecting to the gate 730. A via V₀ 821 is formed over the CA formation 770, which is connected to the CB layer 760, thus connecting the via V₀ 821 to the gate 731.

Above the 3^{rd} layer 844, a dielectric capping layer 860 is formed. Portions of the dielectric capping layer 860 is removed (e.g. etched) in order to allow for connections to portions of the 3^{rd} layer 844. The 4^{th} layer 846 is formed above the dielectric capping layer 860.

On the 4^{th} layer 846, a plurality of M1 metal formations 830, 831 are formed. Therefore, the 4^{th} layer is the M1 layer. An M1 metal formation 830 is formed over the via V₀ 820, thereby connecting the M1 formation 830 to the CB formation 760, and thus, connecting the gate 730 to the M1 formation 830. An M1 metal layer 831 is formed over the via V₀ 821, thereby connecting the M1 formation 831 to the CA 770, which is coupled to the CB formation 760. This provides a connection from the gate 731 to the M1 formation 831. Therefore, a TS cap layer is provided in a two-layer source/drain contact in a finFET device, wherein one layer is a full stripe layer and another layer provides for connections to a metal layer, e.g., M1 layer.

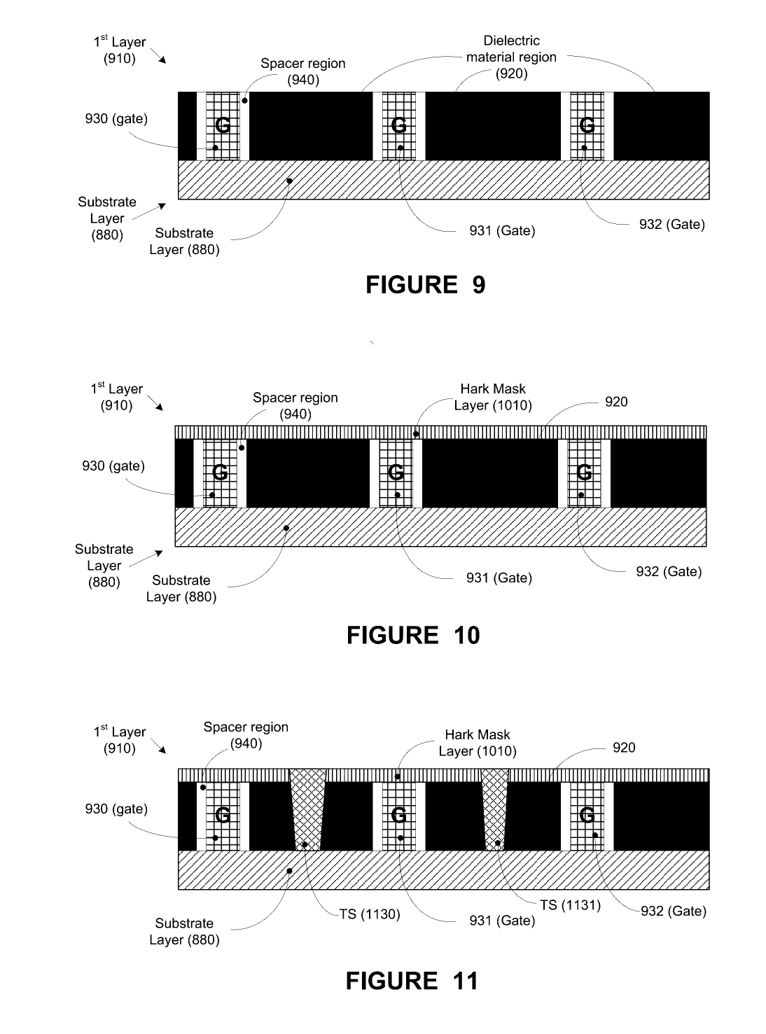

Turning now to FIGS. 9-23, various stylized depiction of the steps for forming finFET device having a continuous active area, in accordance with some embodiments herein, is illustrated.

FIG. 9 illustrates a 1^{st} layer 910 on which a plurality of gate regions 930, 931, 932 are formed on a substrate 960. The 1^{st} layer 910 is formed atop a substrate layer 960. The gate regions 930, 931, 932 are separated by dielectric material regions 920 (e.g., SiO₂). A plurality of spacer regions 940 are formed adjacent to the gate regions 930-932, separating them from the dielectric material regions 920. In one embodiment, the spacer regions may be formed by depositing a nitride material into regions adjacent to the gate regions 930-932.

As shown in FIG. 10, a hard mask layer 1010 is formed over the 1^{st} layer 910. The hard mask layer 1010 provides isolation to prevent access to the gates 310-302, as well as to the dielectric material regions 920. In order to selectively provide electrical connections to portion of the 1^{st} layer 910 (e.g., certain gates 930-932), portions of the hard mask layer 1010 may be selectively etched. In one embodiment, the hard mask layer 1010 may be a silicon nitride Si₃Ni₄ material.

As shown in FIG. 11, certain portions of the gate capping material 1010 may be removed to form structures within the dielectric regions 920 and/or over selected gates 930-932. A plurality of TS structures 1130, 1131 may be formed within the 1^{st} layer 910. The TS structure 1130 may be wider that the TS structure 1131.

In order to form the TS structures 1130, 1131, a plurality of TS patterns may be defined by a lithography process for opening the dielectric layer 920 for forming source/drain regions. An etch process may be applied for removing part of a hard mask 1010 and dielectric material 920 for opening up the areas defined for TS patterns. A silicidation material may be deposited in the openings/trenches as defined by the TS patterns, for forming source and drains regions.

Upon creating trenches as defined by the lithography process for forming the TS structures, a conductive material (e.g., tungsten) may be filled into the TS trenches. This process forms the TS structure 1130 and 1131. In one embodiment, a planarization process may be performed to smooth the surface of the first layer 910.

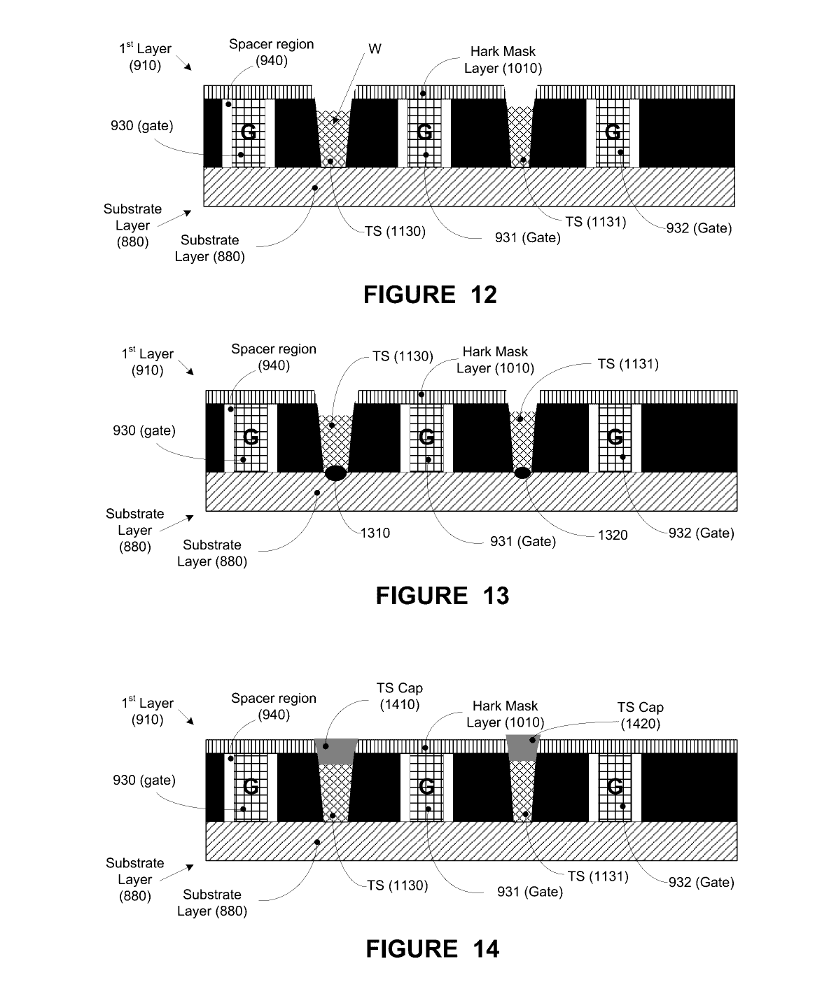

An etch process is then performed to expose the TS formations 1130 and 1131, as depicted in FIG. 12. The TS formations 1130, 1131 are etched such that the top of these formations are below the top portions of the gate capping layer 1010. That is, a portion of the hard mask material 1010 and the dielectric material 920 may be removed to expose the TS formations 1130 and 1131, wherein the top portion of these formations are below the top portions of the hard mask layer 1010 and the dielectric material layer 920.

A plurality of nickel silicide (Ni₂Si) structures 1310, 1320 may be formed respectively adjacent to the TS formations 1130, 1131, as depicted in FIG. 13. The Ni₂Si structures 1310, 1320 are formed to provide a reduction in the resistivity of the electrical connections of TS structures 1130, 1131. The dimensions of the Ni₂Si structures 1310, 1320 are determined by the desired amount of resistivity TS structures 1130, 1131. In one embodiment, the nickel silicide formation is performed after the dielectric etching process and prior to the tungsten deposition process.

The spaces above the TS formations 1130, 1131 are then filled with a TS capping material, as depicted in FIG. 14. A TS cap 1410 is formed over the TS formation 1130, and a TS cap 1420 is formed over the TS formation 1131. Generally, the TS capping 810 prevents connections to the TS formations 1130, 1131. The TS caps 1410, 1420 are formed along the full run of the TS formations 1130, 1131, wherein portions of the TS caps 1410, 1420 may be selectively etched away to allow for specific access to the TS formations 1130, 1131 at desired locations.

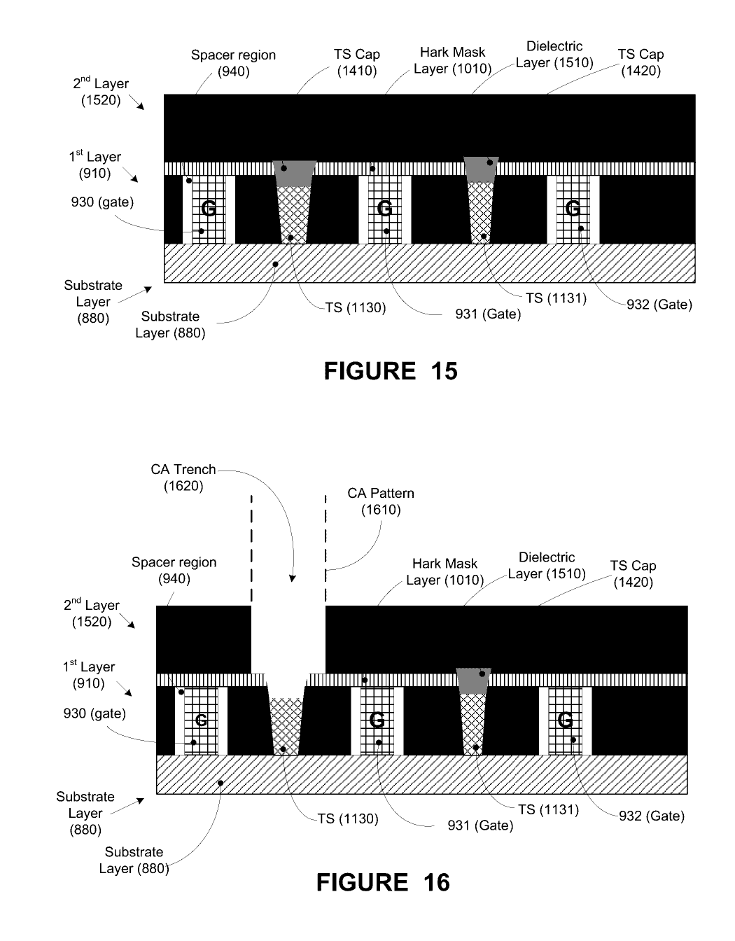

A 2^{nd} layer 1520 is formed over the 1^{st} layer 910, as depicted in FIG. 15. The 2^{nd} layer includes a dielectric layer 1510 being deposited over the hard mask layer 1010 and the TS caps 1410, 1420. In one embodiment, the dielectric layer 1510 may be a silicon oxide (SiO₂) layer.

A CA formation may be formed in the 2^{nd} layer 1520. Upon the dielectric layer 1510, an opening pattern (i.e., CA pattern 1610) for forming a CA formation is defined (e.g., using a lithography process), as depicted in FIG. 16. The CA pattern 1610 is formed over the TS formation 1130 for creating connection to a source/drain region.

Further, a selective etch process may be performed over the CA pattern 1610 to create an opening for a CA formation in the dielectric layer 1510. This etch process also removes the TS cap 1410 in order to expose the TS formation 1310. This results in a CA trench 1620. The TS cap 1420 remains over the TS formation 1131, providing isolation.

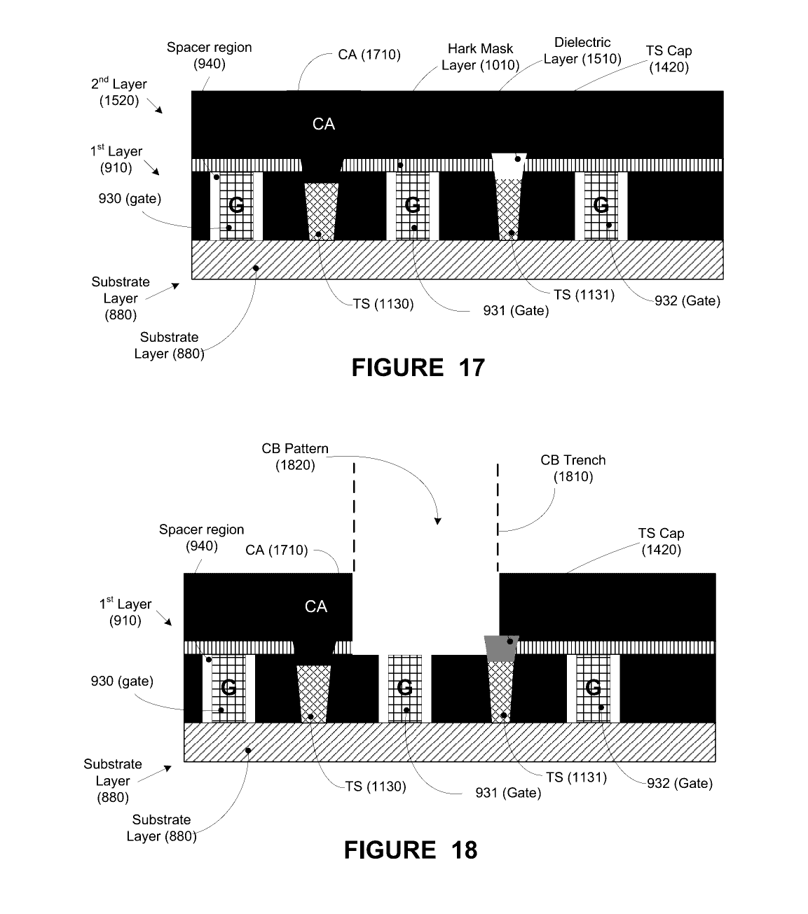

Once the portion of the dielectric layer 1510 defined by the CA pattern 1610 is removed, along with the TS cap 1410, the resultant CA trench 1620 is filled with a conductive material (e.g., tungsten), as depicted in FIG. 17. The filling of the CA trench 1620 results in a CA formation 1710 over the TS formation 1130. A planarization process may then be performed to planarize the CA formation 1710 and the dielectric layer 1510. Thus, an electrical connection between the TS formation 1130 and the CA formation is provided for further processing. In one embodiment, the same conductive material may be used for forming both the CA and CB formations. In this case, the CA trench may be formed, followed by forming a CB trench (as described below with regard to FIG. 18). This may be followed by filling the same conductive material (e.g., tungsten) into both the CA trench and the CB trench. That is, the CA trench formation of FIG. 17 and the CB trench formation of FIG. 18 (below) may be performed sequentially, followed by filling of these trenches using a conductive material.

As a further modification to the dielectric layer 1510, another opening pattern (i.e., CB pattern 1810) for forming a CB formation is defined, e.g., using a lithography process, as depicted in FIG. 18. The CB pattern 1810 may be defined such that a CB formation can be formed to encompass the gate region 931 as well as surrounding spaces, including providing for contacting the CA formation 1710. The CB pattern 1810 is formed over the gate formation 931 for creating an electrical connection to gate.

A selective etch process may be performed over the CB pattern 1810 to create an opening for a CB formation in the dielectric layer 1510. This etch process also selectively removes the gate capping material 1010 over a gate (e.g., gate 931) that requires a CB contact. This etch process exposes the gate region 931. This results in a CB trench 1820. The TS cap 1420 remains over the TS formation 1131, providing isolation from a CB formation that would be formed in the CB trench 1820.

Once the portion of the dielectric layer 1510 is removed, along with a portion of the gate capping layer 1010, the resultant CB trench 1820 is filled with a conductive material (e.g., tungsten), as depicted in FIG. 19. The filling of the CB trench 1820 results in a CB formation 1910 over the gate 931. The CB formation 1910 is formed over the gate 931 and the spacers 940, and in this example, is sufficiently wide for allowing electrical contact with the CA pattern 1710. A planarization process may then be performed to planarize the CB formation 1910. Thus, an electrical connection between the gate 931 and the CB formation is provided for further processing.

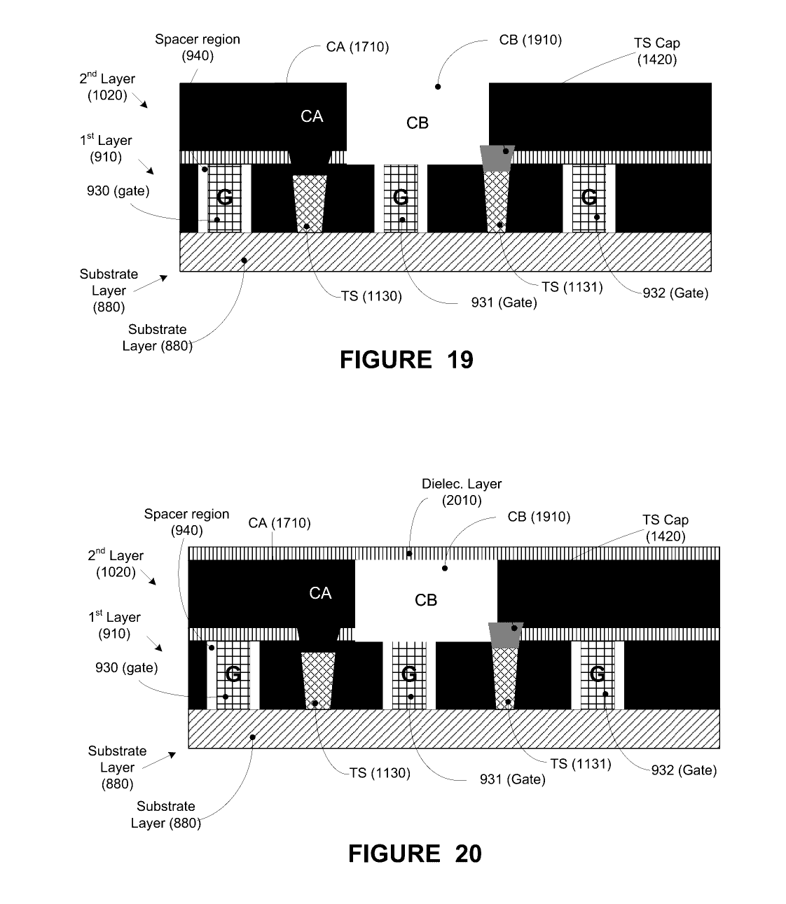

As shown in FIG. 20, a hard mask layer 2010 is formed over the 2^{nd} layer 1520. The hard mask layer 2010 provides isolation to prevent access to the CA and CB formations 1710, 1910, as well as to the dielectric material regions 1510 without selectively etching away portions of the layer 2010. In one embodiment, the hard mask layer 2010 may be a silicon nitride Si₃Ni₄ material.

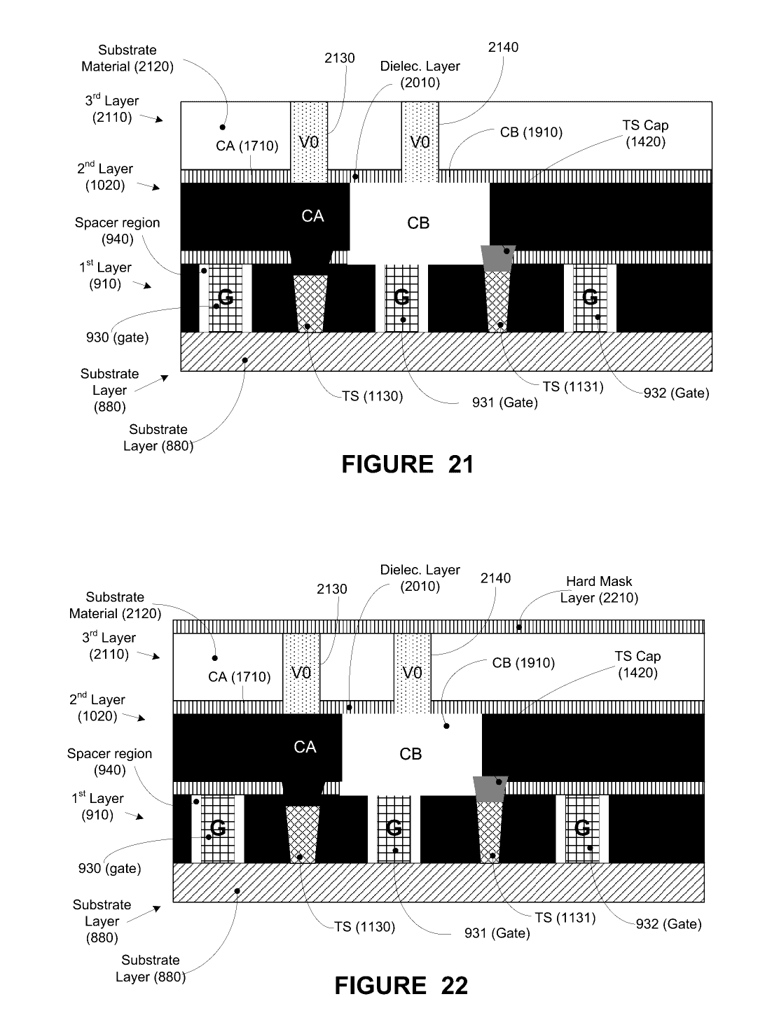

As depicted in FIG. 21, a 3^{rd} layer 2110 may be formed over the 2^{nd} layer 1520. The 3^{rd} layer 2110 may comprise a substrate portion 2120 formed over the hard mask layer 2010. A portion of the hard mask layer 2010 over the CA formation 1710 and the CB formation 1910 is etched to expose the CA and CB formations 1710, 1910. The exposed portions may be filled with conductive material to form vias. A first via 2130 is formed in the substrate 2120, over the CA formation 1710. A second via 2140 is formed in the substrate 2120, over the CB formation 1810.

As shown in FIG. 22, a hard mask layer 2210 is formed over the 3^{rd} layer 2210. The hard mask layer 2210 provides isolation to prevent access to the vias 2130, 2140, as well as to the substrate layer 2120 without selectively etching away portions of the layer 2210. In one embodiment, the hard mask layer 2210 may be a silicon nitride Si₃Ni₄ material.

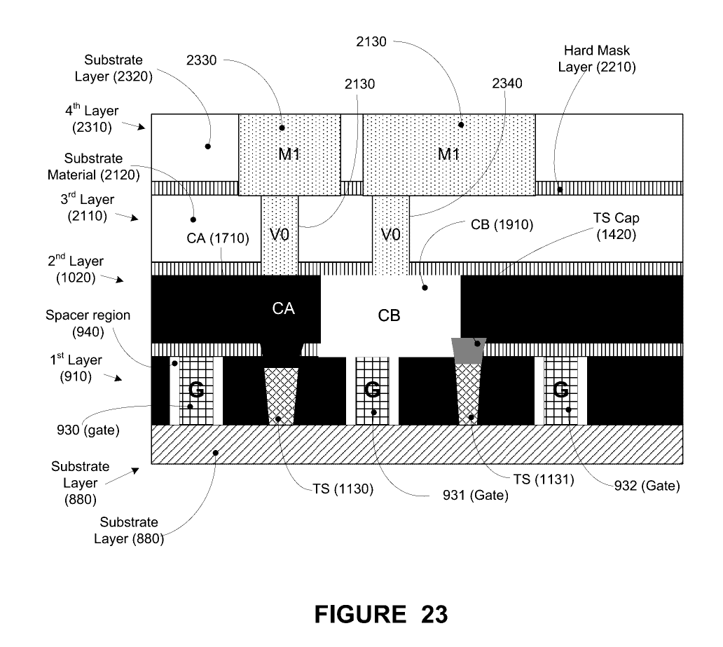

As depicted in FIG. 23, a 4^{rd} layer 2210 may be formed over the 3^{rd} layer 2110. The 4^{rd} layer 2210 may comprise a substrate portion 2320 formed over the hard mask layer 2010. A portion of the hard mask layer 2210 over the vias 2130, 2140 is etched to expose the vias 2130, 2140. The portions of the substrate layer 2310 that are etched away are sufficiently large to form M1 metal formations. The exposed portions may be filled with conductive material to form M1 metal formations.

The M1 metal formations may be formed using copper material, utilizing a double patterning lithography-etch-lithography-etch (LELE) process. A first M1 formation 2330 is formed in the substrate 2320, over the first via 2130. A second M1 formation 2340 is formed in the substrate 2220, over the second via 2140. Thus, a TS-CA connection to a metal layer, along with a gate-CB connection to the metal layer is provided by the exemplary process described in FIG. 9-23. Further processing known to those skilled in the art having benefit of the present disclosure may be used to form the source/drain fins, etc., may be performed to form a finFET device. For example a source/drain fin may be formed above the fourth layer 2210. Various integration processes of forming Metal 1 formations and Via0 can be potentially implemented, such as dual-damascene via first process, dual-damascene trench first process, which however does not affect the process of TS/CA/CB formation, and would remain with the spirit and scope of embodiments herein.

Accordingly, a TS cap layer is provided in a two-layer source/drain configuration in a finFET device having a continuous active area design, wherein one layer is a full stripe layer and another layer provides for a connection to a metal layer, e.g., M1 layer.

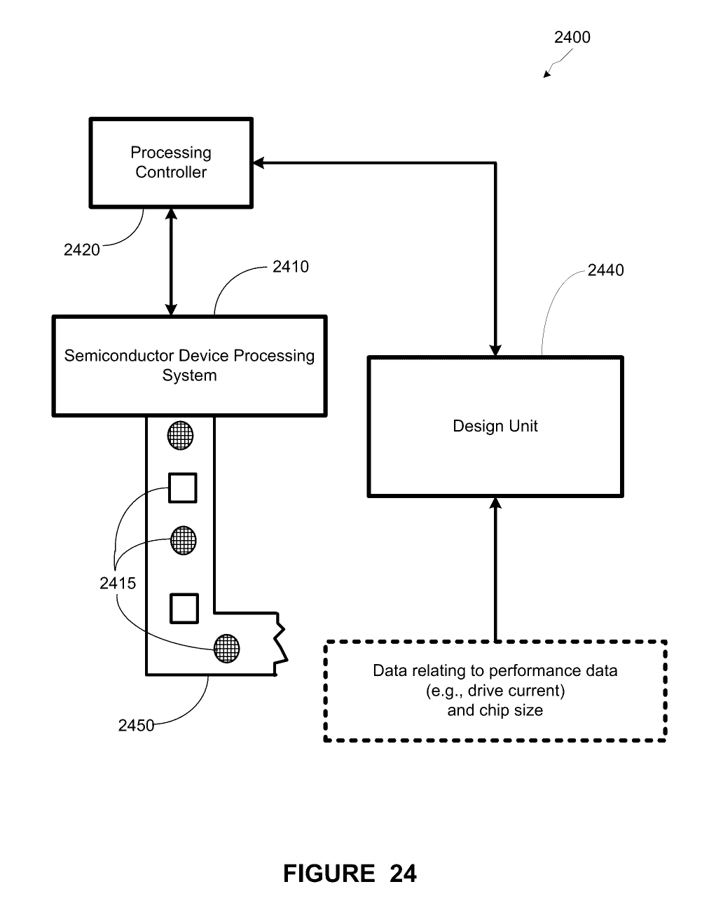

Turning now to FIG. 24, a stylized depiction of a system for fabricating a semiconductor device package comprising a finFET device having a continuous active area, in accordance with embodiments herein, is illustrated. The system 2400 of FIG. 24 may comprise a semiconductor device processing system 2410 and a design unit 2440. The semiconductor device processing system 2410 may manufacture integrated circuit devices based upon one or more designs provided by the design unit 2440.

The semiconductor device processing system 2410 may comprise various processing stations, such as etch process stations, photolithography process stations, CMP process stations, etc. One or more of the processing steps performed by the processing system 2410 may be controlled by the processing controller 2420. The processing controller 2420 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device processing system 2410 may produce integrated circuits on a medium, such as silicon wafers. More particularly, the semiconductor device processing system 2410 produce integrated circuits having finFET devices that comprise source-drain fins that TS cap layer is provided in a two-layer source/drain contact, as described above.

The production of integrated circuits by the device processing system 2410 may be based upon the circuit designs provided by the integrated circuits design unit 2440. The processing system 2410 may provide processed integrated circuits/devices 2415 on a transport mechanism 2450, such as a conveyor system. In some embodiments, the conveyor system may be sophisticated clean room transport systems that are capable of transporting semiconductor wafers. In one embodiment, the semiconductor device processing system 2410 may comprise a plurality of processing steps, e.g., the 1^{st} process step, the 2^{nd} process set, etc., as described above.

In some embodiments, the items labeled “2415” may represent individual wafers, and in other embodiments, the items 2415 may represent a group of semiconductor wafers, e.g., a “lot” of semiconductor wafers. The integrated circuit or device 2415 may be a transistor, a capacitor, a resistor, a memory cell, a processor, and/or the like. In one embodiment, the device 2415 is a transistor and the dielectric layer is a gate insulation layer for the transistor.

The integrated circuit design unit 2440 of the system 2400 is capable of providing a circuit design that may be manufactured by the semiconductor processing system 2410. The integrated circuit design unit 2440 may be capable of determining the number of devices (e.g., processors, memory devices, etc.) to place in a device package. The integrated circuit design unit 2440 may also determine the height of the gate fins, the dimensions TS cap layers, the CA formations, the CB formations, the vias, the metal formations, etc., of the finFET devices. These dimensions may be based upon data relating to drive currents/performance metrics, device dimensions, etc. Based upon such details of the devices, the integrated circuit design unit 2440 may determine specifications of the finFETs that are to be manufactured. Based upon these specifications, the integrated circuit design unit 2440 may provide data for manufacturing a semiconductor device package described herein.

The system 2400 may be capable of performing analysis and manufacturing of various products involving various technologies. For example, the system 2400 may design and production data for manufacturing devices of CMOS technology, Flash technology, BiCMOS technology, power devices, memory devices (e.g., DRAM devices), NAND memory devices, and/or various other semiconductor technologies.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method, comprising:
forming a first gate structure of a continuous active area design in a first layer of a semiconductor wafer;
performing a first hard mask deposition process for depositing a first hard mask layer upon said first layer;
removing a portion of said first hard mask layer based upon a first trench silicide (TS) pattern and a second TS pattern;
forming a first trench silicide (TS) structure and a second TS structure of said continuous active area design in said first layer based upon removing said portion of said hard mask layer, said first and second TS structures being full stripe structures;
depositing a first TS capping layer above said first TS structure and a second TS capping layer above said second TS structure;
removing said first TS capping layer;
forming a source/drain contact structure (CA) above said first TS structure in a second layer of said semiconductor wafer; and
forming a gate contact structure (CB) above said gate structure in said second layer.

2. The method of claim 1, wherein said CB structures is formed adjacent to said CA structure to electrically couple said CA and CB structures.

3. The method of claim 1, further comprising
performing a second hard mask deposition process for depositing a second hard mask layer upon said second layer;
removing a portion of said second hard mask layer based upon a first via pattern and a second via pattern in a third layer of said semiconductor wafer;
forming a first via above said first CA structure based upon said first via pattern; and
forming a second via above said CB structure based upon said second via pattern.

4. The method of claim 2, further comprising
performing a third hard mask deposition process for depositing a third hard mask layer upon said third layer;
removing a portion of said third hard mask layer based upon a first metal pattern and a second metal pattern in a third layer of said semiconductor wafer;
forming a first metal structure above said first via based upon said first metal pattern; and
forming a second metal structure above said second via based upon said second metal pattern; and
wherein said first TS structure is electrically connected to said first metal layer and said gate is electrically connected to said second metal structure.

5. The method of claim 3, wherein said continuous active area design is used to manufacture a finFET transistor.

6. The method of claim 5, further comprising forming a source fin structure and drain fin structure for forming said finFET transistor.

7. The method of claim 3, wherein said forming said first metal layer comprises forming said first metal layer using a lithography-etch-lithography-etch (LELE) process.

8. The method of claim 2, wherein forming said first CA structure comprises forming a via-type structure.

9. The method of claim 3, further comprising:
depositing a first dielectric material in said first layer;
depositing a second dielectric material in said second layer; and
depositing a third dielectric material in third first layer.

10. The method of claim 1, further comprising performing a planarization process subsequent to forming said first TS and said second TS structure.

11. The method of claim 1, further comprising forming a nickel silicon structure on said first and second TS structures for increasing the resistivity of said first and second TS structures.

12. The method of claim 1, further comprising forming spacer regions adjacent to said first gate structure.

13. A fin field effect transistor (finFET) comprising:
a gate structure in a first layer;
a full stripe first trench silicide (TS) structure in said first layer;
a full stripe second trench silicide (TS) structure in said first layer
a TS capping structure formed above said second TS structure;
a source/drain contact structure (CA) formed above said first TS structure in a second layer, said CA capable of being electrically coupled to a first via on a third layer; and
a gate contact structure (CB) electrically coupled to said CA, said CB being electrically isolated from said second TS structure resulting from said TS capping structure.

14. The finFET of claim 13, further comprising:
a second via operatively coupled to said CB on said third layer;
a first metal structure electrically coupled to said first via on a fourth layer; and
a second metal structure electrically coupled to said second on said fourth layer; and
a source/drain fin formed above said first metal structure.

15. A finFET of claim 14, wherein said first metal structure is an M1 metal structure formed by a lithography-etch-lithography-etch (LELE) process; and wherein said second metal structure is an M1 metal structure.

16. A finFET of claim 13, wherein said finFET further comprises:
a first hard mask layer that is selectively etched to form said TS capping structure above said second TS structure; and
a second hard mask layer that is selectively etched to form said first via above CA and form said second via above said CB.

17. A system, comprising:
a semiconductor device processing system to manufacture a semiconductor device comprising at least one fin field effect transistor (finFET); and
a processing controller operatively coupled to said semiconductor device processing system, said processing controller configured to control an operation of said semiconductor device processing system;
wherein said semiconductor device processing system is adapted to:
form a first gate structure of a continuous active area design in a first layer of a semiconductor wafer;
perform a first hard mask deposition process for depositing a first hard mask layer upon said first layer;
remove a portion of said first hard mask layer based upon a first trench silicide (TS) pattern and a second TS pattern;
form a first trench silicide (TS) structure and a second TS structure of said continuous active area design in said first layer based upon removing said portion of said hard mask layer, said first and second TS structures being full stripe structures;
deposit a first TS capping layer above said first TS structure and a second TS capping layer above said second TS structure;
remove said first TS capping layer;
form a source/drain contact structure (CA) above said first TS structure in a second layer of said semiconductor wafer; and
form a gate contact structure (CB) above said gate structure in said second layer.

18. The system of claim 17, wherein semiconductor device processing system is further adapted to:
perform a second hard mask deposition process for depositing a second hard mask layer upon said second layer;
remove a portion of said second hard mask layer based upon a first via pattern and a second via pattern in a third layer of said semiconductor wafer;
form a first via above said first CA structure based upon said first via pattern; and
form a second via above said CB structure based upon said second via pattern.

19. The system of claim 17, wherein semiconductor device processing system is further adapted to:
perform a third hard mask deposition process for depositing a third hard mask layer upon said third layer;
remove a portion of said third hard mask layer based upon a first metal pattern and a second metal pattern in a third layer of said semiconductor wafer;
form a first metal structure above said first via based upon said first metal pattern; and
form a second metal structure above said second via based upon said second metal pattern; and
wherein said first TS structure is electrically connected to said first metal layer and said gate is electrically connected to said second metal structure.

20. The system of claim 17, further comprising a design unit configured to generate a first design comprising a definition for said TS structure, said CA structure, said CB structure, said first and second vias, and said first and second metal structures, wherein data from said design unit provide a integrated circuit design for manufacturing said finFET device using process controller to control an operation of said semiconductor device processing system.
